(19) United States
(12) Patent Application Publication
(10) Pub. No.: US 2007/0286309 A1
(43) Pub. Date: Dec. 13, 2007

(54) Digital broadcast receiving device and controlling method for the same

(76) Inventors: Tomohiko Shigeoka, Yokohama (JP); Tohru Nojiri, Tokyo (JP); Takehiko Nagano, Kawasaki (JP)

Correspondence Address: MCDERMOTT WILL & EMERY LLP, 600 13TH STREET, N.W., WASHINGTON, DC, 20005-3096, US

(21) Appl. No.: 11/723,187

(22) Filed: Mar. 16, 2007

(30) Foreign Application Priority Data
Apr. 4, 2006 (JP) 2006-102640

(51) Int. Cl. H03K 9/00

(52) U.S. Cl. 375/316; 375/E07.001

(57) ABSTRACT

A digital broadcast receiving device comprises a receiving part for receiving a digital broadcast signal including first identifying information and a control part, and the control part compares the first identifying information included in the digital broadcast signal received at the receiving part and second information included in the digital broadcast receiving device, and limits or stops at least one of a plurality of functions included in the digital broadcast receiving device based on the comparison. That prevents the digital broadcast receiving device with a troubled software program being used as it is.

### CROSS-REFERENCE TO RELATED APPLICATION

This application claims priority from Japanese Patent Application JP2006-102640, filed on Apr. 4, 2006, the content of which is hereby incorporated by reference into this application.

### BACKGROUND OF THE INVENTION

The present invention relates to a digital broadcast receiving device.

In the digital broadcast receiving device, it is known to download a software program for updating by using an electric wave sent from a broadcast station and update the software program to shoot a trouble or to improve a function of the software program for executing a function or the like for the device body. For example, the Non-Patent document 1 (by Yagi, Yoshimura, Kato, “An approach to a digital broadcasting technology”, Ohm Co. Ltd., 2005, (p. 154 to p. 161)) discloses the matters below as to downloading of a software program. First, prior to the downloading broadcasting of such a software program, announcement information including schedule information of the downloading broadcasting is broadcast from the broadcast station. Then, at the side of a receiver, when the receiver receives the announcement information, receiving of the download is reserved based on the schedule information included in the announcement information and the time for broadcasting the download broadcast is waited for. When the time for broadcasting the download broadcast comes, broadcast updating software program is automatically downloaded and received.

### SUMMARY OF THE INVENTION

In the above-mentioned conventional art, however, if a trouble occurs to a software program in the device, for example, the digital broadcast receiving device is used with the troubled software since the announcement information is broadcasted until the software program is actually download broadcasted.

In the above-mentioned case, it is preferable that a time period in which a digital broadcast receiving device is used with the troubled software program should be shortened.

In the digital broadcasting, a viewer makes a contract with the broadcast station (provider), pays a predetermined rate, and is granted authority of viewing a desired channel/program. Here, when a digital broadcast receiving device is stolen, an unauthorized third party may view the contracted channel/program.

In the digital broadcasting, two-way data communication such as the online-shopping is available. Thus, if the digital broadcast receiving device is stolen, information kept in the receiving device is abused to buy something.

The present invention is adapted in view of the above problem, and intends to provide a technique that can enhance security by preferably limiting functions of the digital broadcast receiving device.

In order to achieve the above-mentioned object, the present invention provides a technique below. That is to say, the present invention has a receiving part for receiving a digital broadcast signal including first identifying information, and a control part, wherein the control part compares the first identifying information included in the digital broadcast signal received by the receiving part and second identifying information included in the digital broadcast receiving device, and limits or stops at least one of a plurality of functions included in the digital broadcast receiving device based on the comparison.

According to the configuration, if a software program of the device body has a trouble, or if the device body is stolen, operations of the function of the device that is determined by the identifying information in the digital broadcast signal broadcasted from the broadcast station can be limited.

The present invention has a receiving part for receiving a digital broadcast signal including first identifying information, a control part, storage part for storing connected device identifying information including second identifying information on a device connected to the digital broadcast receiving device, and an information sending/receiving part, wherein the control part compares the first identifying information included in the digital broadcast signal received by the receiving part and the second identifying information included in the connected device information, and the information sending/receiving part sends information for limiting functions of the connected device to the connected device based on the comparison.

According to the above configuration, if a software program of the device body connected to the digital broadcast receiving device has a trouble, or if a stolen device body is connected to the digital broadcast receiving device, operations of the function of the device that is determined by the identifying information in the digital broadcast signal broadcasted from the broadcast station can be limited.

According to the present invention, security of the digital broadcast receiving device can be enhanced.

Other objects, features and advantages of the invention will become apparent from the following description of the embodiments of the invention taken in conjunction with the accompanying drawings.

### BRIEF DESCRIPTION OF DRAWING

FIG. 1 is a block diagram of the entire of an embodiment of the present invention;

FIG. 2 is a diagram showing a detailed example of a digital broadcast receiving device in the present invention;

FIG. 3 is a diagram showing an example of identifying information in the present invention;

FIG. 4 is a diagram showing an example of a function state table in the present invention;

FIG. 5 is a diagram showing an example of function limiting information in the present invention;

FIG. 6 is an example of a flowchart of function limiting processing in the present invention;

FIG. 7 is an example of a flowchart showing the case where the limited function is requested in the present invention;

FIG. 8 is a block diagram of the entire of an embodiment of the present invention for limiting a function by receiving the function limiting information as a proxy;

FIG. 9 is a diagram showing a detailed example of the device connected with the digital broadcast receiving device in the present invention;

FIG. 10 is a diagram showing an example of a connected device table in the present invention;

FIG. 11 is a flowchart of processing to store identifying information of the connected device in the present invention;

FIG. 12 is a flowchart of processing to send the function limiting information in the present invention;

FIG. 13 is a flowchart of receiving of the function limiting information as a proxy in the present invention;

FIG. 14 is a flowchart of limiting of function by unique determining information in the present invention;

FIG. 15 is a diagram showing a detailed example of the digital broadcast receiving device in the present invention;

FIG. 16 is a diagram showing an example of a connected device table in the present invention;

FIG. 17 is a flowchart of determination of whether the contents corresponding to the function limitation as a proxy is needed or not in the present invention;

FIG. 18 is a flowchart of receiving the contents corresponding to the function limitation as a proxy in the present invention; and

FIG. 19 is a flowchart of function recovering by using the contents corresponding to the function limitation in the present invention.

### DETAILED DESCRIPTION OF THE INVENTION

Embodiments for implement the present invention will be described below.

Components with the same functions in the description below and those shown in the diagrams are denoted by the same reference numerals even if they are in different devices. The elements to store information are denoted by the same reference numeral if they need not to be distinguished, even if different information is stored in different devices. If the components denoted by the same reference numerals are described once, they are omitted from the description again even if they are described in the drawings in other embodiments.

Those with a different function in another embodiment or those required to be distinguished in another device are denoted by different reference numeral.

An embodiment of the present invention will be described with reference to the drawings.

The term “limitation of a function” in the embodiments below refers to stop all or a part of operations of the function. For example, degeneracy and the like of a function in a software program are included.

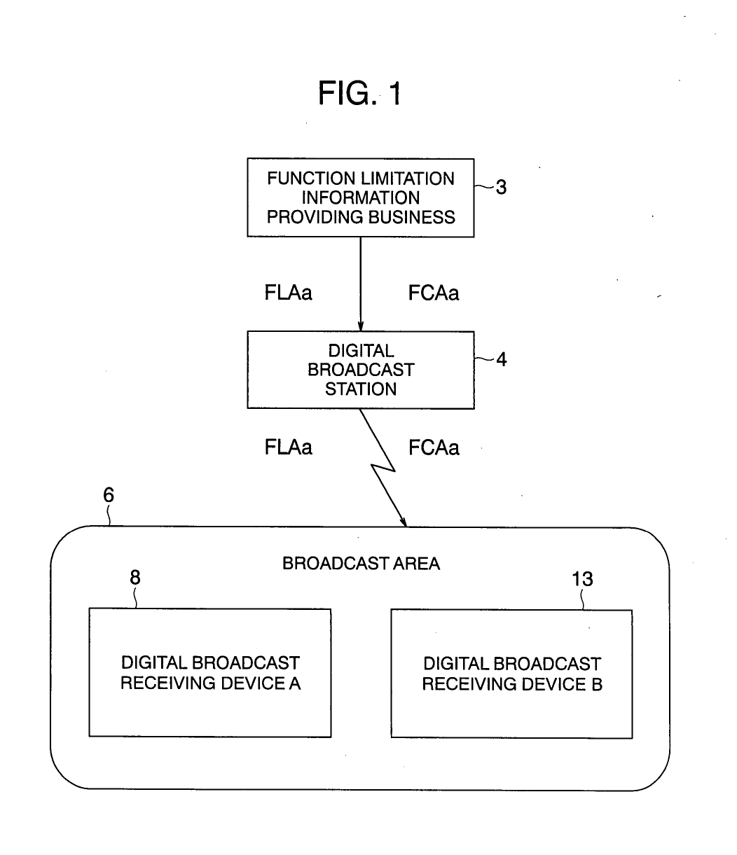

FIG. 1 is a diagram showing an example of a configuration of the entire system including the digital broadcast receiving device of the first embodiment. As shown in FIG. 1, the embodiment includes a function limitation information providing business 3, function limitation information FLAa provided by the function limitation information providing business 3, a function limitation corresponding contents FCAa, a digital broadcast station 4 that airs digital broadcast, a broadcast area 6 that can receive broadcast from the digital broadcast station 4, and a digital broadcast receiving device A8 and a digital broadcast receiving device B13 in the broadcast area 6. Here, the function limitation information providing business 3 is a proxy of a manufacture of a TV display device, an audio player, a data receiving device, a digital broadcast receiving device such as a data display device, a manufacturer of a system or a device including them, or a manufacture that creates a stored software program for them, a seller or an owner of them, or a proxy of them.

The digital broadcast station 4 broadcasts the function limitation information FLAa and the function limitation information FCAa provided from the function limitation information providing business 3.

When an operation of a specific function of the digital broadcast receiving device is in trouble, or if the digital broadcast receiving device has a problem in security, the function limitation information FLAa is broadcasted to limit the specific function for reducing influence by the problem. For example, it is implemented if performance of the device may be affected due to a trouble of the function, if the device is invalidly operated or abused by a user other than the authorized user, or if the device may be stolen by someone other than the authorized user.

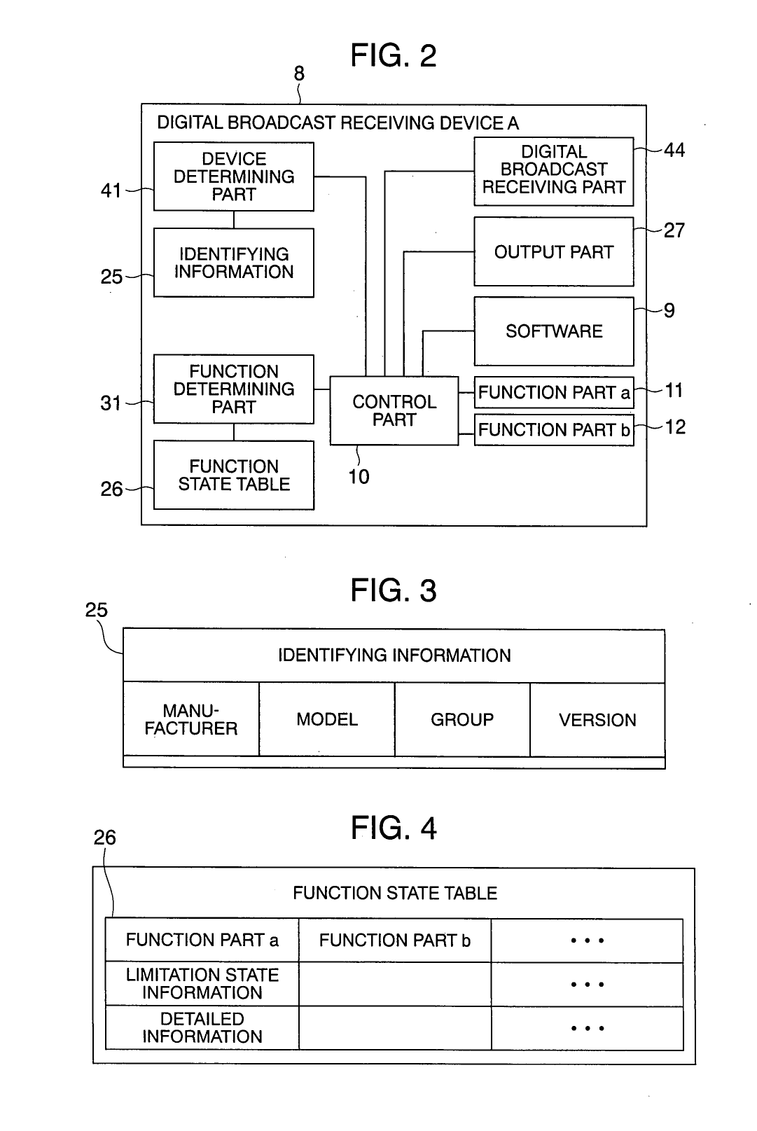

FIG. 2 shows an example of a digital broadcast receiving device in the embodiment.

The digital broadcast receiving device A8 shown in FIG. 2 has a digital broadcast receiving part 44, a plurality of function part such as a function part all, a function part b12, a control part 10 for controlling the function parts, with a software program 9 relating to control of the function part, for example. The function has identifying information 25 for identifying the device, a device determining part 41 for treating the identifying information 25, a function state table 26, and a function determining part 31 for treating the function state table 26, further with an output part 27 for outputting an image, audio, data and the like, for example. The function state table 26 keeps information whether operations of each function part is in a non-limited state or a limited state.

In the embodiment described below, various types of information are described as components of each device. It is assumed that all of the information and the information table are kept in the storage part such as a memory included in each device.

The digital broadcast receiving device B13 shown in FIG. 1 has the same configuration as the inner configuration of the digital broadcast receiving device A8 shown in FIG. 2, for example, except for identifying information 25, and data stored in the function state table 26.

Although the software program 9, the control part 10 and the function part 11 and the like are described in parallel in the description of FIG. 2 inside the digital broadcast receiving device, the function part 11 and the like may be implemented on the software program 9 in the embodiment. That is to say, the function part may be included in the software program. If the function part is included in a software program, the term “limitation of operations of the function part” refers to degeneracy of the function part in the software program. That is the same in all the digital broadcast receiving device or a device connected to the digital broadcast receiving device to be described below.

Although the output part of the digital broadcast receiving device shown in the description of FIG. 2 are also described in other descriptions below, it is not necessarily included except for the case the output part is used.

The configuration inside the digital broadcast receiving device shown in FIG. 2 shows that respective part is connected and adapted centering on the control part. In this configuration, the same component may be used for both the device determining part 41 and the control part 10, or the same component may be used for both the function determining part 31 and the control part 10. The processing or determination performed by the device determining part 41 of the flowchart to be described later may be performed by the control part 10. Similarly, the processing or determination performed by the function determining part 31 may be performed by the control part 10. That is the same in any of the flowcharts.

The connection is not limited to that shown in FIG. 2 if only the connection enables a function of various flowchart or the procedures to be described later. The condition of the configuration inside the digital broadcast receiving device is common to inner configuration of all the devices to be described later.

Now, the identifying information 25 and the function state table 26 will be described below.

As shown in FIG. 3, the identifying information 25 includes information indicating a manufacturer of the digital broadcast receiving device A8, information indicating model and the like, information indicating a group and the like into which devices are classified, and information indicating a version of the device. The term the “version” of the device refers to information indicating a level of updating the device relating to a function and the like of the device, and it may be include updating version information of a software program, for example, or may include information including a history of hardware updating of the device.

The function state table 26 is a table storing limitation state information indicating whether the function is limited or not, or detailed information that is data on operations of the function part or data relating to the limitation state for each function part of the digital broadcast receiving device A8 as shown in FIG. 4.

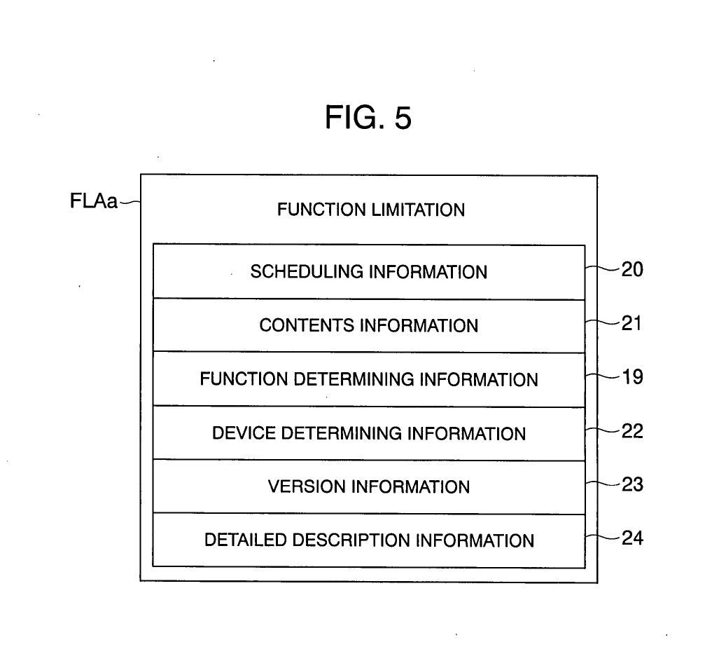

FIG. 5 is a diagram showing an example of function limitation information. The function limitation information FLAa includes scheduling information 20, contents information 21, function determining information 19, version information 23, detailed description information 24 and the like, for example. The schedule information 20 includes information on date and time and channel to broadcast the function limitation corresponding contents FCAa, for example. The function determining information 19 includes information for determining the function part with a problem such as a trouble of the operation, for example. The contents information 21 includes whether the limited function limitation corresponding contents need to be distributed or not or detailed information on the function limitation corresponding contents. The device determining information 22 includes information on a manufacturer or the model of the objective device of the function limitation. In the embodiment, it is shown that the objective device of the function limitation is the digital broadcast receiving device A8, for example. The version information 23 includes information on the version of the device to which the function limitation corresponding contents FCAa is applied. The detailed information 24 includes text information for describing that the function is limited and cannot be used for the user.

The function limitation information FLAa does not necessarily include all types of information. Information that is the prerequisite of the system configuration may be omitted, and unneeded information may be omitted from the viewpoint of the system.

The above-mentioned function limitation information FLAa may be announcement information for contents download in the digital broadcast, or may be included or include the announcement information.

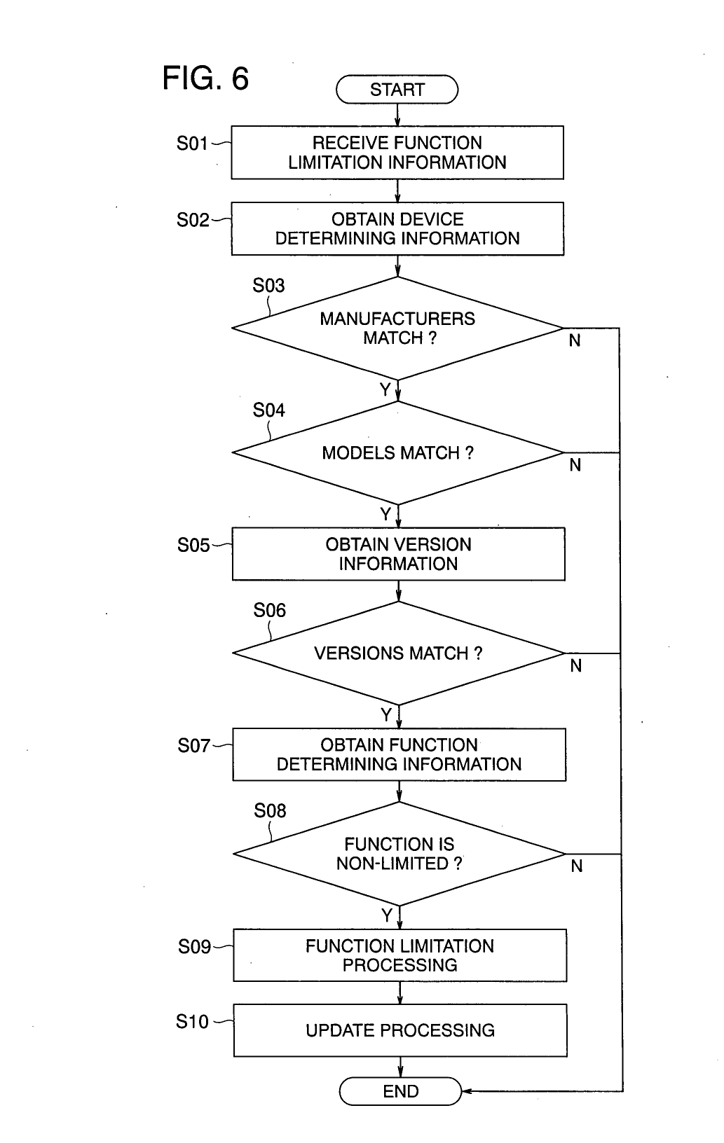

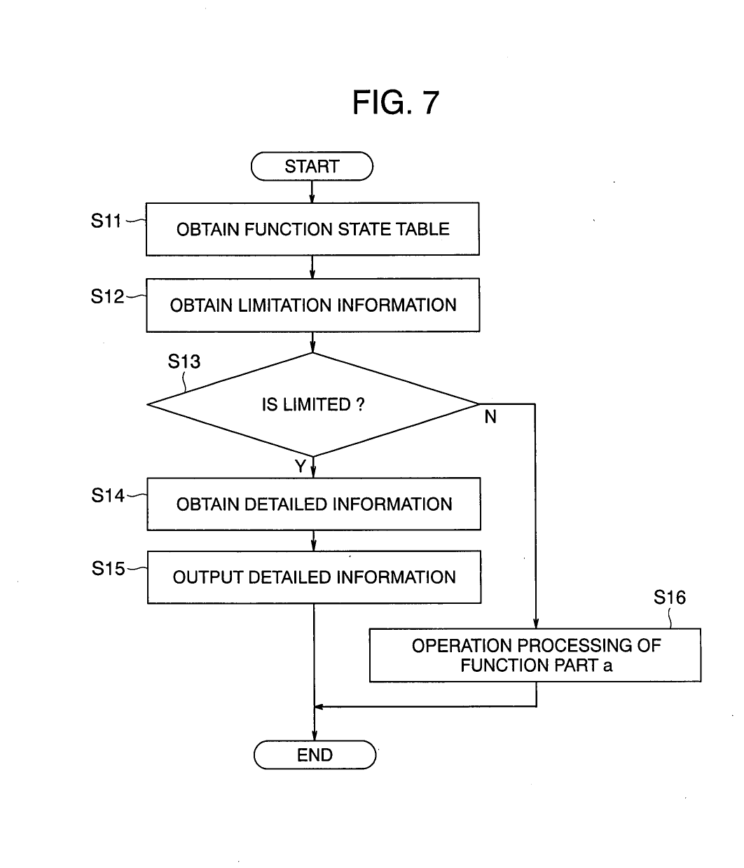

Next, an example of the procedure of the function limitation by the digital broadcast in the system shown in FIG. 1 and FIG. 2 will be described by using the flowcharts of FIG. 6 and FIG. 7. First, at the step S01, the digital broadcast receiving device A8 receives the function limitation information FLAa. At the step S02, the device determining part 41 obtains the device determining information 22 in the function limitation information FLAa. At the step S03, the device determining part 41 compares manufactures of the device determining information 22 and the identifying information 25, and if they do not match, it finishes the processing, and if they match, it proceeds to the next step. At the step S04, the device determining part 41 compares models of the device determining information 22 and identifying information 25, and if they do not match, it finishes the processing, and if they match, it proceeds to the next step. At the step S05, the control part 10 obtains the objective version information 23 in the function limitation information FLAa. At the step S06, the control part 10 compares the objective version information 23 and the version of the identifying information 25, and if they do not match, it finishes the processing, and if they match, it proceeds to the next step. At the step S07, the function determining part 31 obtains the function determining information 19 in the function limitation information FLAa. At the step S08, the function determining part 31 compares information on the function to be limited included in the function determining information 19 and limitation state information of the function in the function state table 26, and if the function to be limited has been the limitation state, it finishes the processing, and if the function to be limited is in the current non-limited state, it proceeds to the next step. Next at the step S09, the control part 10 implements limitation on the function to be limited. Next at the step S10, various types of information below are updated. The term “update of the various types of information” here refers to such that the function determining part 31 or the control part 10 updates the limitation state information of the function state table 26 of the functions to be limited into a limited state, or obtains the detailed description information 24 in the function limitation information FLAa and updates the detailed information of the function state table 26 of the functions to be limited. The device determining part 41 or the control part 10 may update the version of the identifying information 25.

The various determination and function of the above-mentioned flowchart may be limited as such each of the processing parts or the determination part may limit in conjunction with the software program 9, or only each of the processing parts or determination part may limit on the software program 9. That is the same in all the flowcharts shown below.

With the processing of the flowchart of FIG. 6, if the digital broadcast receiving device A8 is included in the device to be limited of the device determining information 22 of the function limitation information FLAa and the digital broadcast receiving device B13 is not included there, and if the function part a is included in the function to be limited of the function determining information 19 and the function part b is not included there, operations of the function part a is limited and operations of the function part b is not limited as a result of the processing in the flowchart of FIG. 6 in the digital broadcast receiving device A8. Also in the digital broadcast receiving device A013, neither the function part a nor the function part b is limited as a result of the processing performed in the same procedure as that in the flowchart of FIG. 6.

Therefore, with the procedure shown in the flowchart in FIG. 6, only the specific function in the specific device has been limited.

FIG. 7 is a flowchart for describing an example of operations of the control part 10 when operations of respective function parts are requested after the function limitation has completed. At the step S11, the control part 10 obtains the function state table. At the step S12, the control part 10 obtains limitation state information on the function part a from the function state table 26. At the step S13, if the function state information indicates the non-limitation state, the processing proceeds to the step S16; and if it indicates the limited state, the processing proceeds to the step S14. At the step S14, the control part 10 obtains the detailed information on the function part a from the function state table 26. The detailed information includes description of the function limitation, for example, to a user. At the step S15, the control part 10 presents the obtained detailed information to the user through the output part 27, and finishes the processing. If the function is not limited, at the step S16, the control part 10 performs an operation requesting of the function part all and finishes a series of the processing.

The function determining part 31 may perform a part of those treating the function state table among respective processing parts and respective determination parts.

At the step S15, a means for the control part 10 to present the detailed information to the user through the output part 27 may be included in the digital broadcast receiving device A8 or may be included in a appliance connected to the digital broadcast receiving device A8. The means may be an image display means, an audio output means or a data presenting means.

A method for releasing the function limitation after the function limitation processing has completed is performed in the manner below, for example.

The first example of the function limitation releasing method is a method for broadcasting the function limitation information of the limitation release if a problem such as a trouble in the function limitation objective device is no longer a problem by a changed environment or the like. That is to say, the limitation release information FRAa (not shown), which is information for releasing limitation, is broadcasted instead of the function limitation information FLAa shown in FIGS. 1, 5 and 6. By replacing the function limitation information FLAa in the flowchart of FIG. 6 by the limitation release information FRAa and limitation processing in respective processing and determination by the limitation releasing processing, a limitation releasing processing flowchart of operations of the limited function part can be displayed. The limitation release information FRAa may be included in the function limitation corresponding contents FCAa. The obtaining way of the limitation release information FRAa is not limited to the digital broadcast and may be obtained through a network connected to the device AA8 or through an external recording medium. The obtaining means may be a user input means. The limitation releasing may be performed by control from an external controlling device connected to the device A8.

The second example of the function limitation releasing method is a method for updating a software program that controls the function part. A method for downloading an updating software program and updating the software program is performed in the way below, for example. First, the function limitation information FLAa is caused to play a role of the announcement information for downloading a software program in the digital broadcast. Next, if the function limitation corresponding contents FCAa are the updating software program, the second example can be implemented by using a method by using digital broadcast that is described in the Non-Patent Document 1. The method for obtaining the updating software program is not limited to the digital broadcast. Thus, the obtaining method can be that through a network connected to the digital broadcast receiving device A8 or that for obtaining from an external recording medium. The obtaining may be performed in the manner in which the updating software program is sent from an external control device connected with the digital broadcast receiving device A8.

The entire system for broadcasting the function limitation corresponding contents FCAa by the digital broadcast, which is an example of a method for releasing function limitation in the embodiment, is shown by switching FLAa in FIG. 1 with FRAa. If broadcast of the function limitation corresponding contents FCAa is with relatively large amount of data such as an updating software program, it is effective by taking the manner below. Thus, the digital broadcast receiving device is adapted to automatically receive the function limitation corresponding contents FCAa from a broadcasting channel specified by the obtained scheduling information 20 during the broadcasting time. Thus, it is effective as a system because the function limitation release is performed transparent to the user, for example, and a user is saved from such a trouble of checking the presence of the broadcast of the function limitation corresponding contents FCAa often by an access means via a network.

If the function limitation release is performed in the above-mentioned manner, the version included in the identifying information 25 may be updated with information for making the version of releasing of the function limitation apparent. For example, if the function limitation is released by eliminating the trouble in the function with the updating of the software program as mentioned-above, the version information 23 including the identifying information 25 may be updated based on the updating software program after the software program is updated.

According to the above embodiment, if a software program in the digital broadcast receiving device has a trouble, information on the function limitation is broadcasted before the software program involving downloading is subjected to updating or the like so that the device can receive the function limitation information and limit a specified function. Thus, a time period in which the digital broadcast receiving device is used with the troubled state as it is can be shortened. That can enhance security of the device.

The second embodiment of the present invention will be described.

The embodiment limits the function by the digital broadcasting even if the device to be subjected to the function limitation is a digital broadcast receiving device but no in a state that it can receive the broadcasting, or if the device to be subjected to the function limitation has no digital broadcast receiving part.

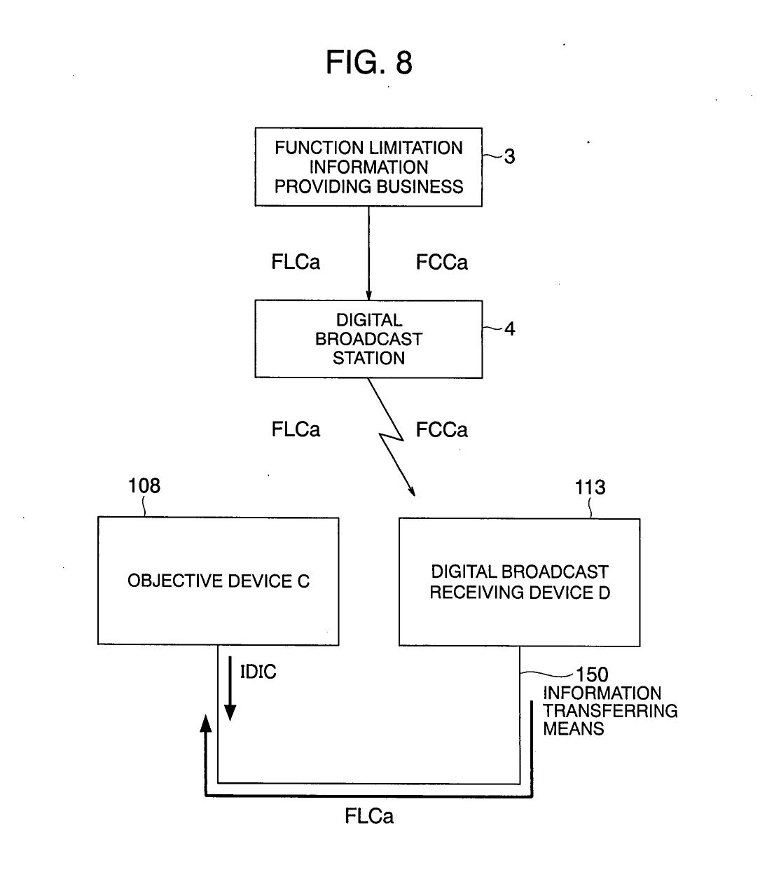

FIG. 8 is a diagram showing an example of the entire configuration of the system of the embodiment. The components in the system in FIG. 8 different from those in FIG. 1 are described with the reference numeral different from those in FIG. 1.

The digital broadcast station 4 is the same component as that in FIG. 1, thus, it is omitted from the description. The function limitation information providing business 3 is a business that is a manufacturer of a device connected with the device described in the first embodiment at the information transferring part other than the device described in the first embodiment, or a manufacture that creates an integral software program thereof or a seller or an owner of the integral software or an agent thereof.

In the embodiment, the objective device of the function limitation information of the function limitation information FLCa or the function limitation corresponding contents FCCa is not only the digital broadcast receiving device and the device connected to the digital broadcast receiving device.

The objective device C108 and the digital broadcast receiving device D113 are, for example, connected by the same network of the information transferring part 150. As mentioned above, the broadcast receiving device D113 in FIG. 8, a branch to connect to other appliance or a network can be intervene there. They are the same in the information transferring part described below.

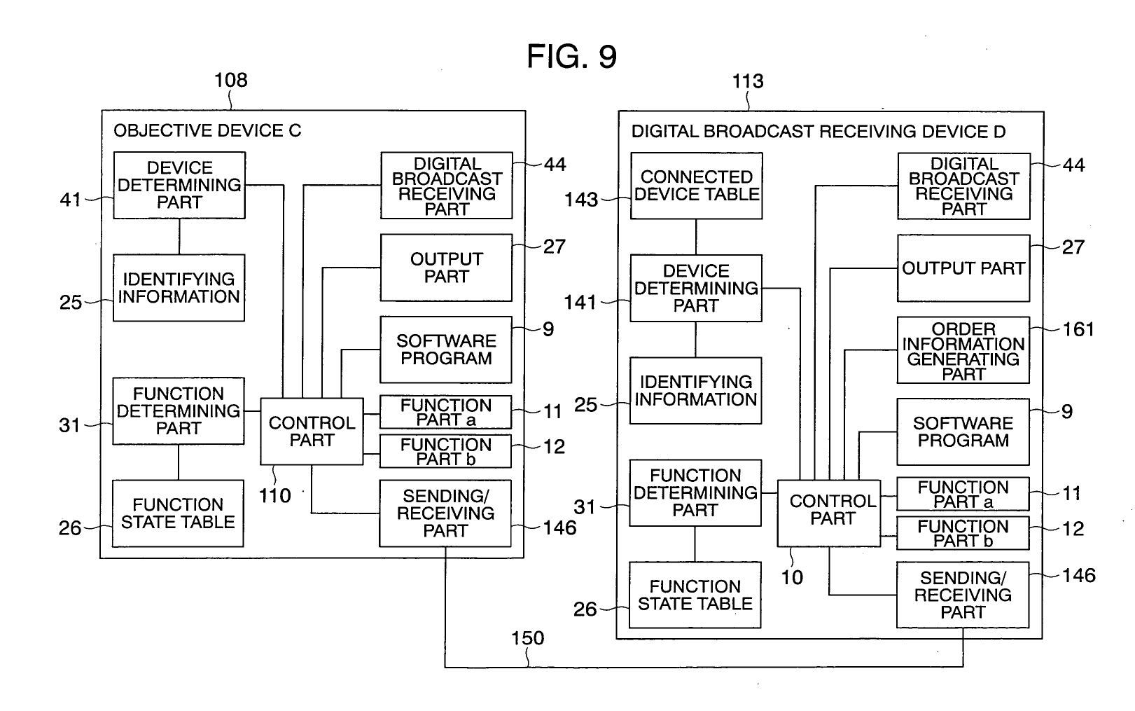

FIG. 9 is a diagram showing an example of an inner configuration of each device in the embodiment. It will be described below. In FIG. 9, an inner configuration of the objective device C108 and an inner configuration of the digital broadcast receiving device D113 descried in FIG. 8 are shown. First, in the embodiment, the objective device C108 may or may not include the digital broadcast receiving device. For simplicity of description, the embodiment will be described by a configuration with the digital broadcast receiving part. The objective device C108 is different from the digital broadcast receiving part A8 in FIG. 2 in that it is connected with the information transferring part 150 via a sending/receiving part 146 and that it can input and output information on the information transferring part 150. Next, the digital broadcast receiving device D113 is different from the digital broadcast receiving device A8 in FIG. 2 in that it is connected with the information transferring part 150 via the sending/receiving part 146, that it can input and output information to and from the information transferring part 150 and that it has the connected device table 143. The device determining part 141 also treats the connected device table 143. objective device C108 may be the digital broadcast receiving device or an appliance that does not have the digital broadcast receiving part in the embodiment. Here, the information transferring part 150 is assumed as a general Ethernet (registered trademark) LAN, but a wired or a wireless LAN other than the Ethernet (registered trademark) or a digital interface such as IEEE 1394 or the like may be used. For example, the objective device C108 transmits the identifying information IDIC on the information transferring part 150, for example. Here, the identifying information IDIC is the same information as the identifying information 25 in the first embodiment and the information whose data stored therein corresponds to the device C. Also, the digital broadcast receiving device D113 may transmit the identifying information IDID on the information transferring part 150. As that needs not to be described in the present invention, it is not shown in the figure. Further, the digital broadcast receiving device D113 sends the received function limitation information FLCa to the objective device C108 via the information transferring part 150.

Although no other device is shown on the information transferring part 150 in FIG. 8, other device such as a PC or a server may intervene there in the information transferring part 150. Although the information transferring part 150 is described to connect only the objective device C108 and the digital Here, the connected device table 143 keeps a device address of the connected device that is connected to the digital broadcast receiving device D113 by the information transferring part 150 and identifying information, and when it receives the function limitation information corresponding to the connected device, it can store them. For example, in the example of FIG. 9, in the connected device table 143, the device address of the objective device C108, the identifying information of the device and the received function limitation information are kept.

The sending/receiving part 146 shown in FIG. 9 is replaced by a wireless sending/receiving part for data transmission if the information transferring part 150 is a wireless transferring means. When data is sent and received via the information transferring part 150 by the flowchart or the like shown below, all the sending/receiving part 146 perform sending/receiving data. Controlling of the sending/receiving of the sending/receiving part 146 may be performed by the control part 10. That is the same in all the embodiments to be described below.

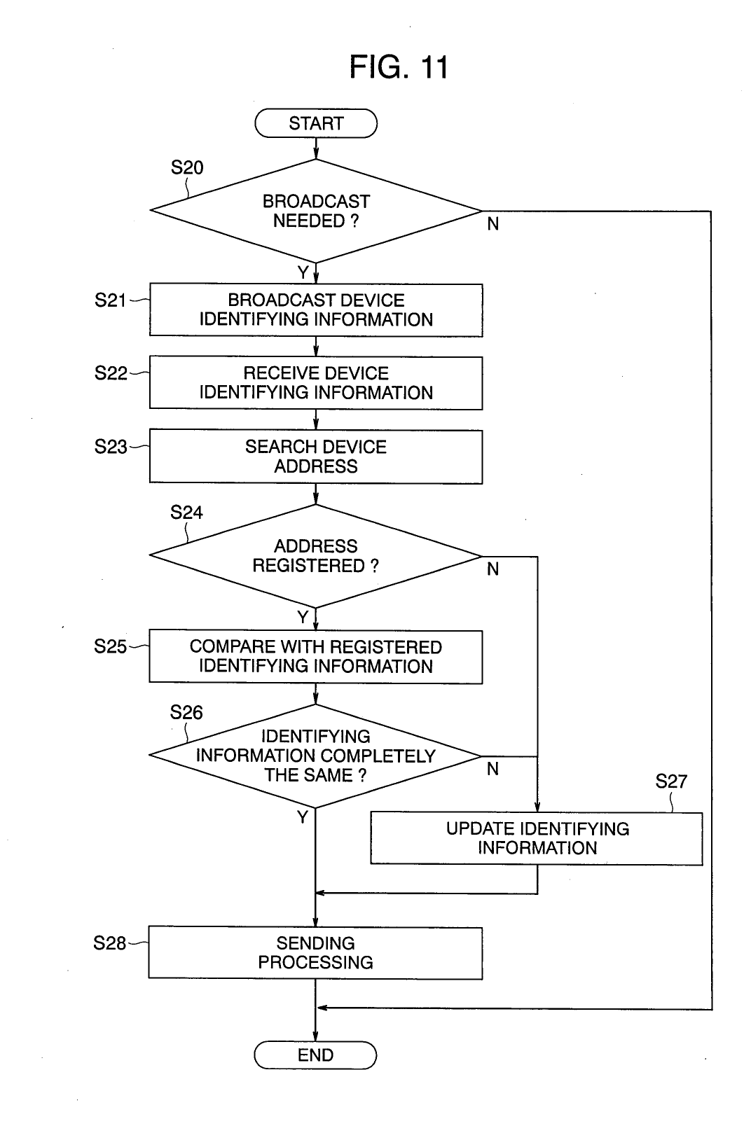

Next, an example of a procedure by which the digital broadcast receiving device D113 stores the identifying information of the objective device C108 in the connected device table 143 and sends the function limitation FLCa to the objective device C108 will be described with reference to the flowchart of FIG. 11.

The term “broadcast” shown below refers to a case where a device transmits information to anther device connected thereto, for example, via the information transferring part. The destination of the information may be a single or plural.

First, at the step S20, it is determined whether the objective device C108 needs broadcast of the device identifying information. The case where broadcast is required includes for example if a certain period of time passed since the broadcast of the previous device identifying information, or if the function limitation information is to be changed from a state of being able to receive to a state of not being able to receive, or if the function limitation information is changed from a state of not being able to receive to a state of being able to receive. If it needs broadcast, the processing proceeds to the next step; and if it does not need broadcast, the processing ends. At the step S21, the objective device C108 in FIG. 9 broadcasts the identifying information IDIC of itself to the information transferring part 150 such as a network in FIG. 8. At the step S22, the digital broadcast receiving device D113 receives the identifying information IDIC broadcasted at the step S21 via the information transferring part 150. At the step S23, the device determining part 141 of the digital broadcast receiving device D113 in FIG. 9 searches the connected device table 143 for the sending device address of the identifying information IDIC. At the step S24, if the sending device address of the identifying information IDIC is found in the connected device table 143, the processing proceeds to the step S25; and if it is not found, the processing proceeds to the step S27. At the step S25, the device determining part 141 compares the identifying information corresponding to the sending device address found in the connected device table 143 and the received identifying information IDIC. At the step S26, if the compared identifying information is the same, the processing proceeds to the step S28; and if it does not match, the processing proceeds to the step S27. At the step S27, the device determining part 141 or the control part 10 updates a set of the identifying information IDIC received it the connected device table 143 and the sending device address and registers the set. Here, if it is a registered address, it updates only the identifying information, and if it is an unregistered address, it adds a set of the address and the identifying information. At the step S28, if the digital broadcast receiving device D113 has stored the function limitation information FLCa in the connected device table 143, the device sends the function limitation information FLCa to the objective device C108 via the information transferring part 150.

With the procedure, the digital broadcast receiving device D113 can store the identifying information IDIC of the objective device C108 in the connected device table 143 and the device D113 can send the function limitation information FLCa to the objective device C108.

If the objective device C108 and the digital broadcast receiving device D113 are combined together to be used as a product, i.e., if they are decided to be connected together at the information transferring part, the procedure of the flowchart in FIG. 11 needs not to be taken. In such a case, when they are combined as a product, the identifying information of the objective device C108 only needs to be stored in the connected device table of the digital broadcast receiving device D113 by the means other than the digital broadcast. When it is actually used, a user may store the identifying information of the objective device C108 in the connected device table of the digital broadcast receiving device D113 by manual operation. In such cases, the objective device C108 needs not to be a digital broadcast receiving device. The device C needs not to have a function of broadcast or the like.

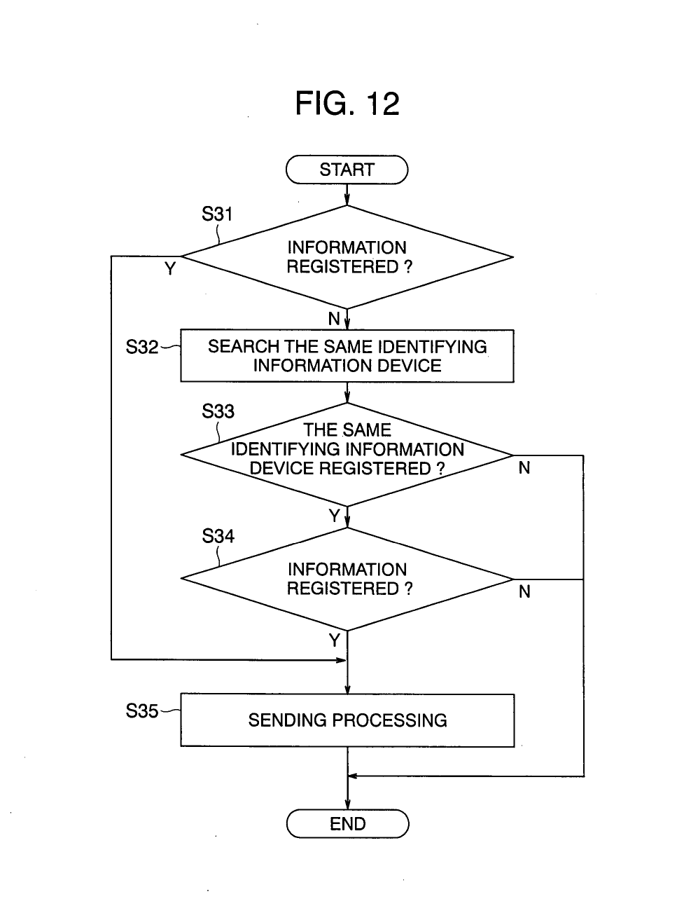

In order to send the function limitation information FLCa to the objective device C108 faster, the processing at the step S28 of the flowchart in FIG. 11 may be performed like the flowchart shown in FIG. 12. That will be described below.

First, at the step S31, the device determining part 141 of the digital broadcast receiving device D113 determines whether the function limitation information FLCa for the searched identifying information or device address has been registered in the connected device table 143 or not. If it is registered, the processing proceeds to the step S35; and if it is not registered, the processing proceeds to the next step. At the step S32, the device determining part 141 of the digital broadcast receiving device D113 searches the connected device table 143 for the device that stores the same identifying information as that of the objective device C108 received in the flowchart of FIG. 11. The model will be called the same identifying information device. At the step S33, if the same identifying information device is registered, the processing proceeds to the next step; and if it is not registered, the processing ends there. At the step S34, if the function limitation information FLCa corresponding to the same identifying information device is registered, the processing proceeds to the next step; and if it is not registered, the processing ends there. At the step S35, the digital broadcast receiving device D113 sends the function limitation information FLCa via the information transferring part 150 to the device that broadcasted the identifying information.

Although an example where the digital broadcast receiving device D113 sends the function limitation information FLCa has been described in the above description, it may be performed like below. Thus, the digital broadcast receiving device D113 only needs to have an order information generating part 161 shown in FIG. 9, generate order information FOCa by the order information generating part 161 based on the function limitation information FLCa, and send the generated order information FOCa to the device that broadcast the identifying information via the information transferring part 150. The term “order information” here is not the broadcasted information FLCa, but refers to that converted into information or a signal that the objective device C can decode, for example. The control part 10 or the order information generating part 161 may determine the objective specified function part based on the function limitation information FLCa, and generate the order information FOCa that limits the specified function part of the objective device based on the result of the determination.

In such a case, in FIG. 8, as replacing the function limitation information FLCa by the order information FOCa, the entire system can be shown.

Although the order information is described by the order information for limiting operations of the specified function part, the order information may be order information for releasing limitation of the function part to release operation limitation of the specific function part.

If the digital broadcast receiving device D113 has the order information generating part in the case where the device broadcasted identifying information does not have the digital broadcast receiving part such that the device cannot decode the function limitation information FLCa that is received as it is, the device can perform operation limitation of the specific function part or limitation release of the specific function part only with a means for receiving the order information from outside.

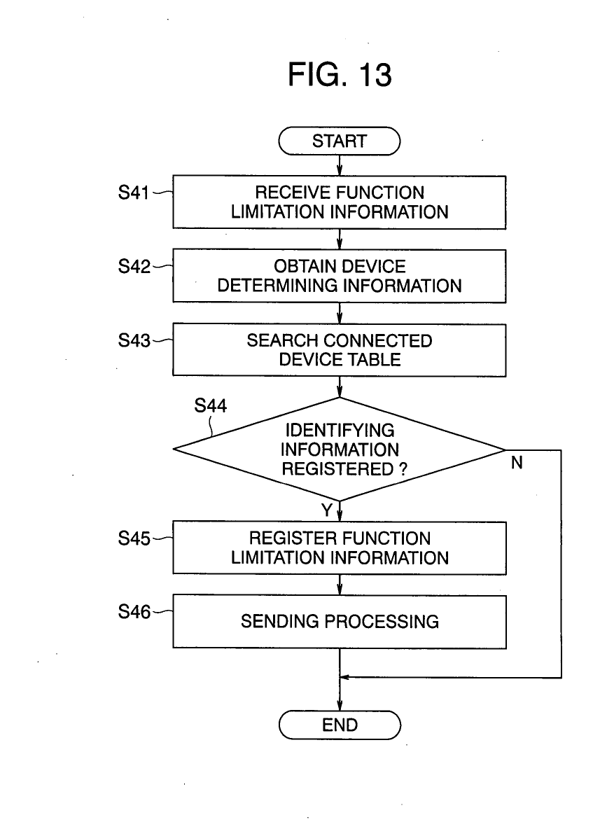

Now, an example where a procedure for the digital broadcast receiving device D113 receives the function limitation information FLCa, stores it in the connected device table 143 and sends the function limitation information FLCa to the objective device will be described with reference to the flowchart of FIG. 13. First, at the step S41, the function limitation information FLCa from the digital broadcast receiving device 4 is received. At the step S42, the digital determining part 141 retrieves the device determining information included in the function limitation information FLCa. At the step S43, the device determining part 141 searches the connected device table for the device having the identifying information determined by the device determining information. At the step S44, if the identifying information has been registered, the processing proceeds to the next step; and if it has not been registered, the processing ends there. At the step S45, the device determining part 141 or the control part 10 registers the received function limitation information FLCa in the function limitation information storing part of the device determined in the connected device table 143. At the step S46, the digital broadcast receiving device D113 sends the function limitation information FLCa to the device address registered in the connected device table 143 via the information transferring part 150 with the identifying information.

If the digital broadcast receiving device treats the above-mentioned order information, the order information FOCa instead of the function limitation information FLCa is sent at the step 46.

For respective processes such as the function limitation release after the processing of FIGS. 11, 12 and 13 are implemented and the objective device performed the function limitation processing are the same as those described in the first embodiment.

If the digital broadcast receiving device D has the identifying information determined by the device determining information, operations of the function part included therein may be limited.

With the above-mentioned configuration, if it has the identifying information matching the device determining information, the function limitation information FLCa or the order information FOCa is sent when broadcast from the objective device is done or when the digital broadcast receiving device receives the function limitation information. That enables limitation on operations of the objective information part of the objective device instantaneously.

With the above-mentioned embodiment, if a software program in the device body connected to the digital broadcast receiving device has a trouble, when the information on the function limitation is broadcasted and the digital broadcast receiving device receives the function limitation information, the function limitation information can be sent to the connected device and the connected device can limit the function. Thus, a time period in which the device with the trouble is used as it is can be shortened. That can enhance security of the device.

Now, an embodiment for limiting the function of only the specific unique device especially including the unique determining information unique to the objective device body in the function limitation information will be described.

The embodiment enables the specific body of the function to be determined by including unique determining information unique to the objective device body in the device determining information or contents information of the first or the second embodiment and also including the unique identifying information unique to the device body in the identifying information of the objective device.

In the description below, the configuration of the first embodiment is described with the digital broadcast receiving device and the function limitation information modified to match the present embodiment.

Thus, it is assumed that the present embodiment is the first embodiment further including the unique determining information unique to the function limitation information. It is also assumed that the identifying information 25 of the digital broadcast receiving device has the unique identifying information unique to the device body. The term “unique determining information” refers to information for determining a specific device body such as a production number, a serial number, a user registration number or the like instead of information for determining classification of device such as a manufacture, model or the like of the digital broadcast receiving device.

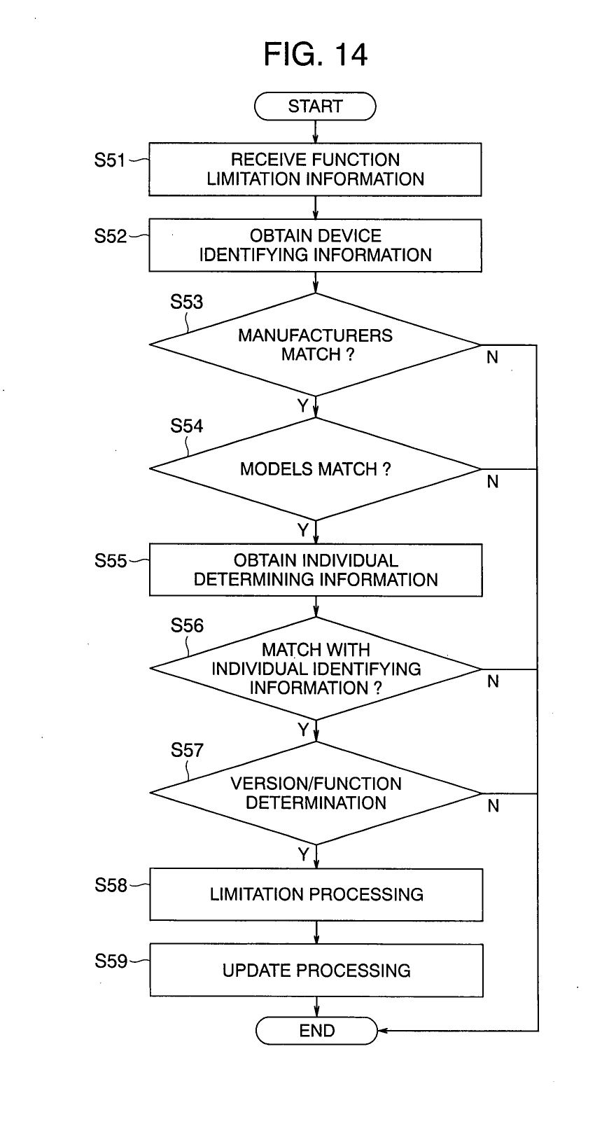

An example of a procedure of limiting a function of a specific body will be described with reference to the flowchart of FIG. 14 by using the unique determining information.

First at the step S51, the objective digital broadcast receiving device receives the function limitation information. At the step S52, the device determining part of the digital broadcast receiving device obtains the device determining information in the function limitation information. At the step S53, the device determining part compares the device determining information and the manufacturer of the device identified by the identifying information in the digital broadcast receiving device. If they do not match, the processing ends there; and if they match, the processing proceeds to the next step. At the step S54, the device determining part compares the device determining information and the model of the identifying information. If they do not match, the processing ends there; and if they match, the processing proceeds to the next step. At the step S55, the device determining part obtains the unique determining information from the device determining information. At the step S56, the device determining part compares the received unique determining information and the unique identifying information included in the identifying information. If they match, the processing proceeds to the next step; and if they do not match, the processing ends there. The step S57 is the step in which steps S05 to S08 are put together, thus, it is omitted from the description. Next at the step S58, the control part limits the limited function. Finally, at the step S59, the digital broadcast receiving device updates various information the same as that of S10 of FIG. 6 and the processing ends there.

The flowchart of the processing after the processing by the flowchart of FIG. 14 when operations of the limited function is requested is the same as that of FIG. 7 of the first embodiment.

Although the unique determining information is included in the device determining information in the embodiment, it may be included in other information such as the contents information or the like.

Although this embodiment is described by an example where the function limitation objective device is the digital broadcast receiving device as in the first embodiment, it may be adapted to make the device connected to the digital broadcast receiving device via the information transferring part as in the second embodiment. In such a case, as in the second embodiment, the function limitation processing can been performed even in the case where the objective digital broadcast receiving device cannot receive the function limitation information by broadcasting. As a result, a time period in which the digital broadcast receiving device with a trouble is used as it is can be shortened.

As such, a time for the specific digital broadcast receiving device with a trouble being used as it is can be shortened by including the unique determining information of the objective device body in the function limitation information. That has an effect to stop the stolen specific device or to prevent information recorded in the device from being abused or the like.

According to the embodiment as descried above, if the digital broadcast receiving device body is stolen or if the stolen device body is connected to the digital broadcast receiving device, operations of the function of the device of the specific body can be limited by the digital broadcast signal broadcast from the broadcast station. That can enhance security of the device.

Now, the fourth embodiment will be described.

The fourth embodiment is like the second embodiment except that the digital broadcast receiving device can send the function limitation corresponding contents to the objective device in addition to the function limitation information. In the description of the fourth embodiment, the digital broadcast receiving device corresponding to the digital receiving device D113 in the second embodiment is replaced by the digital broadcast receiving device E213. The objective device C108 is described as the same as that in the second embodiment. Here, it is assumed that the objective device C108 in the fourth embodiment is limited for operations of the specific function part therein by the same method as that in the first or the second embodiment.

Here, the digital broadcast receiving device E213 in the fourth embodiment not only receives the function limitation information FLCa in place of the objective device C108 but also receives the function limitation corresponding contents FCCa and sends that to the objective device C108. The function limitation corresponding contents FCCa is an updating software program or the like. That will be described in detail below.

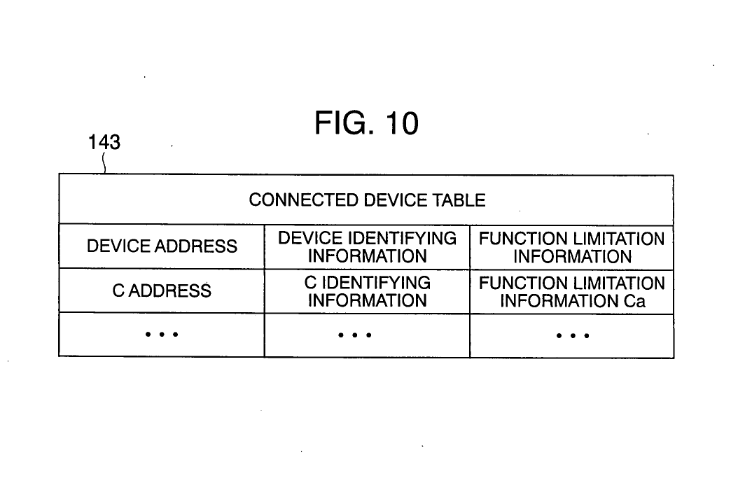

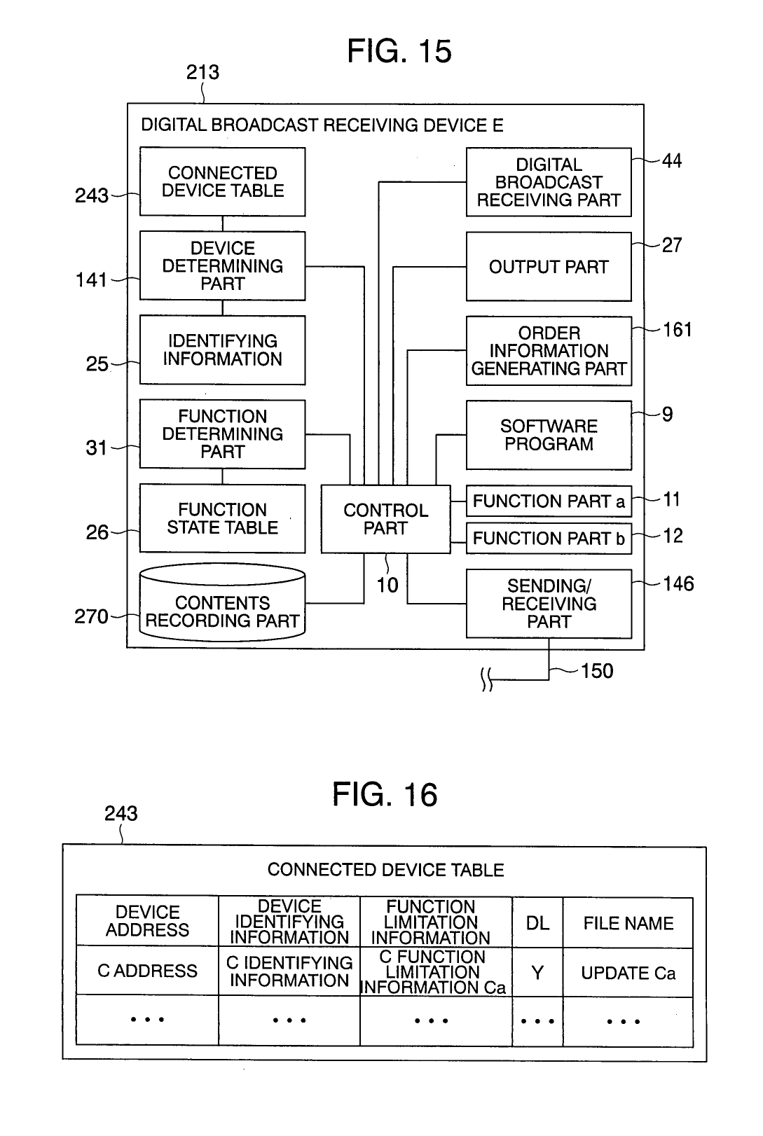

FIG. 15 is a diagram showing an example of an inner configuration of the digital broadcast receiving device E213. The digital broadcast device has the contents recording part 270 to keep the function limitation corresponding contents received as a proxy in addition to a inner configuration of the digital broadcast receiving device D113 of FIG. 9. Although the recording part 270 is described as the device that can be stored on the hard disk device, for example, in the embodiment, it may be other device using other physical medium. The physical medium may be retrieved outside. The physical medium may be placed outside the digital broadcast receiving device E213 and be connected to the device. The connected device table 243 keeps download information and information such as a file name of the function limitation corresponding contents in addition to the function limitation information included in the connected device table 143 shown in FIG. 10. Here, the download information is information indicating whether the function limitation corresponding contents are to be downloaded (DL) or not.

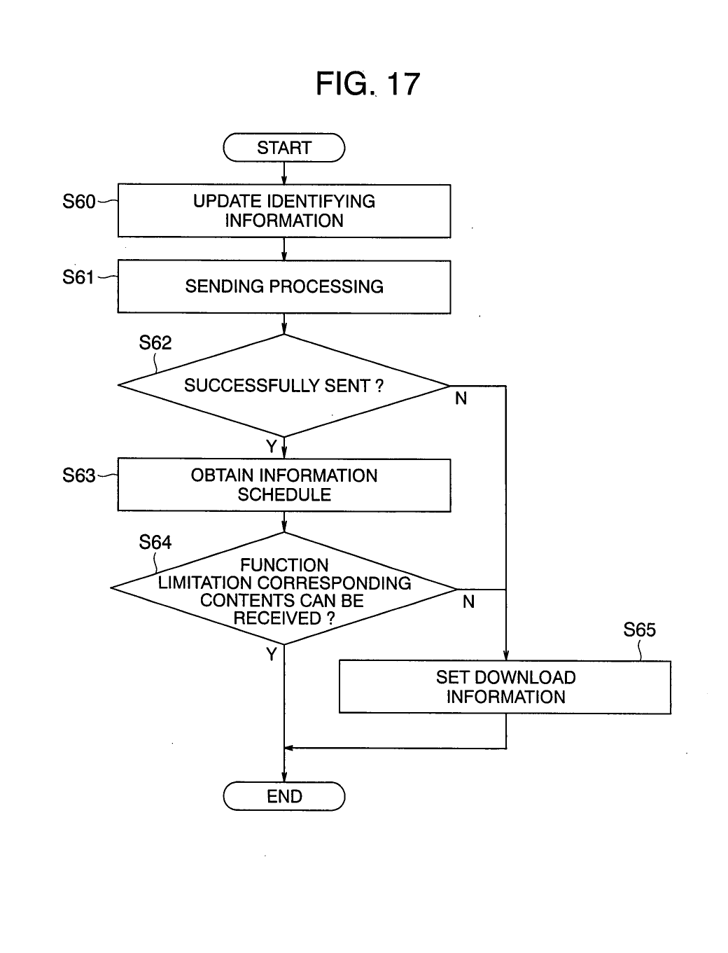

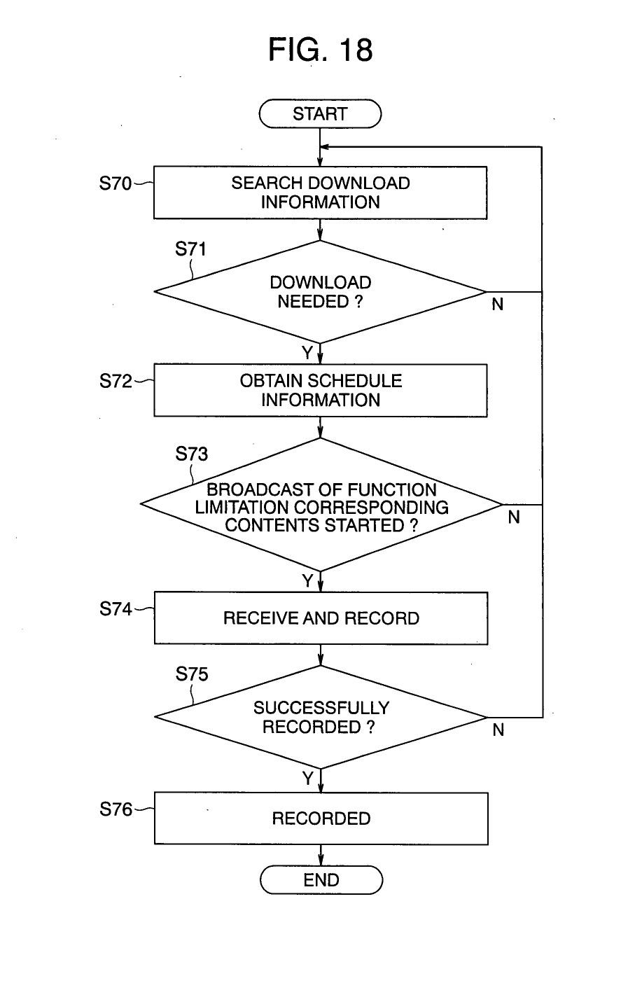

In the description for FIGS. 17 and 18 hereinafter, the objective device C108 is described as having the digital broadcast receiving part.

First, a procedure of setting download information of the connected device table will be described with reference to the flowchart of FIG. 17.

First, at the step S60, the digital broadcast receiving device E213 stores the identifying information IDIC of the objective device C108 in the connected device table 243. The detailed procedure at the step S60 is the same as that at the steps S20 to S27 of FIG. 11. At the step S61, the digital broadcast receiving device E213 sends the function limitation information FLCa stored in the connected device table 243 to the objective device C108 via the information transferring part 150. The detailed procedure at the step S61 is the same as that of the flowchart shown in FIG. 12. At the step S62, the digital broadcast receiving device E213 checks whether the function limitation information FLCa has successfully sent or not. If it has been successfully sent, the processing proceeds to the next step; and if it has aborted, the processing proceeds to the step S65. At the step S63, the objective device C108 obtains the scheduling information from the received function limitation information FLCa. At the step S64, the objective device C108 obtains information on the time when the function limitation corresponding contents included in the scheduling information is broadcasted. The object device C108 determines whether or not it can receive the function limitation corresponding contents based on information on the time. As a result of the determination, if it can be received, the processing ends there, and if it cannot be received, the processing proceeds to the step S65. At the step 65, the objective device C108 informs the digital broadcast receiving device E213 that it cannot receive the function limitation corresponding contents. In response to that, the device determining part 141 of the digital broadcast receiving device E213 sets the download information of the connected device table 243 to “needs to be received” (for example a sign “Y”) and the processing ends there.

Although it is assumed that the objective device C108 has the digital broadcast receiving part in the description of the above FIG. 17, it may not have the digital broadcast receiving part. In this case, the steps S63 and S64 of FIG. 17 are not needed.

Now, a procedure for the digital broadcast receiving device E213 receives the function limitation corresponding contents FCCa as a proxy will be described with reference to the flowchart of FIG. 18. First at the step S70, the device determining part 141 of the digital broadcast receiving device E213 obtains download information on one device in the connected device table 243. At the step S71, the control part 10 determines whether download is needed or not based on the download information of the received device. If download is needed, the processing proceeds to the step S72; and if download is not needed, the processing returns to the first step to search for the next device. At the step S72, the function determining part 141 retrieves the corresponding function limitation information from the connected device table 243 and obtains the scheduling information including information on when the function limitation corresponding contents is broadcasted. At the step S73, if the broadcast of the function limitation corresponding contents is to be started, the processing proceeds to the next step. If the function limitation corresponding contents are not scheduled to be broadcasted, of if it has not started yet, the processing returns to the first step and the next device is searched for in the connected device table 243. At the step S74, the digital broadcast receiving device E213 receives the function limitation corresponding contents and records it in the content recording part 270. Here, the processes for transitioning from the step S73 to the step S74 may be automatically started at the step S74 when time for broadcasting the function limitation corresponding contents comes, for example. Next at the step S75, if the recording has successfully done, the processing proceeds to the next step; and if it aborted, the processing returns to the first step. When the processing returns to the first step, the search for the next device can be started or the download processing on the same device may be repeated. If the download processing on the same device is to be repeated, the upper number of the repetition is preferably set. That can prevent the flowchart from being caught in a repeating endless loop. At the step S76, the device determining part 141 records information such as a file name of the received function limitation corresponding contents and the like in the connected device table 243. Finally, the device determining part 141 updates the download information to be completed and the processing ends there.

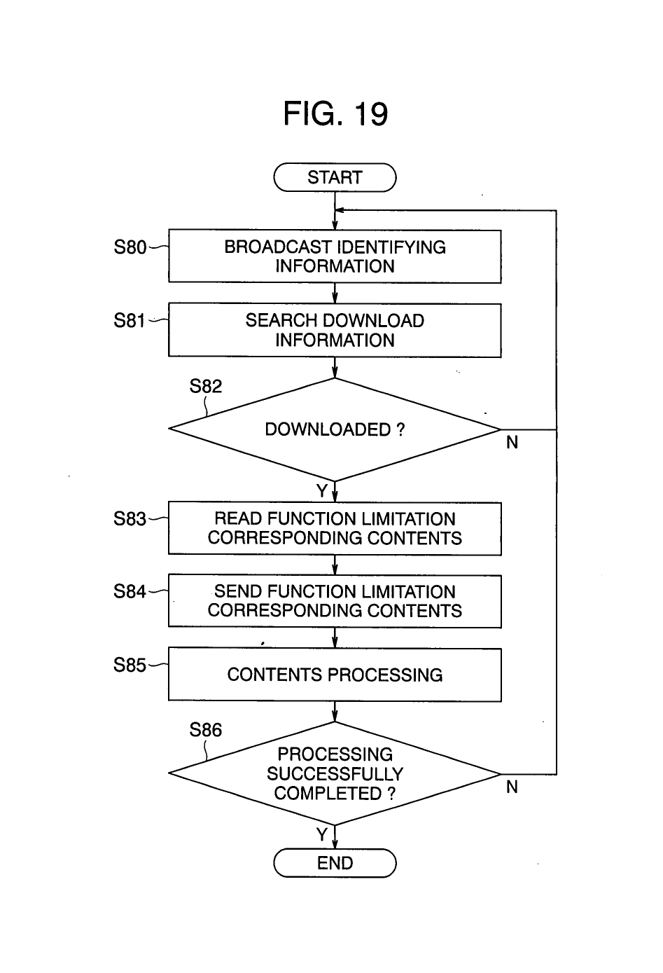

Now, a procedure for the digital broadcast receiving device E213 recovers the limited function of the objective device C108 by using the function limitation corresponding contents FCCa that is received as a proxy will be described by using the flowchart of FIG. 19. First, at the step S80, the objective device C108 broadcasts the identifying information of itself. At the step S81, the device deterring part 141 of the digital broadcast receiving device E213 searches the connected device table 243 for the download information based on the identifying information FLCa of the received broadcast. At the step S82, if the digital broadcast receiving device E213 completed download of the function limitation corresponding contents FCCa, the processing proceeds to the next step; and if it has not completed the download, the processing returns to the first step. At the step S83, the control part 10 of the digital broadcast receiving device E213 reads the function limitation corresponding contents FCCa recorded in the contents recording part 270. At the step S84, the digital broadcast receiving device E213 sends the read function limitation corresponding contents FCCa to the objective device C108 via the information transferring part 150 such as a network. At the step S85, the objective device C108 performs processing using the function limitation corresponding contents FCCa received from the digital broadcast receiving device E213 and recovers the limited function. Here, that the limited function is recovered by using the function limitation corresponding contents includes, as described in the first embodiment, a case where the function limitation corresponding contents includes an updating software program and the limited function is recovered by updating the software program, for example, and the limitation is released. Alternatively, limitation on the function may be released by using the data or the like included in the function limitation corresponding contents. Finally at the step S86, if the processing at the step S85 successfully ends, the objective device C108 ends the processing; and if it aborted, the processing retures to the first step.

At the step S80, the objective device C108 implements the broadcast. The broadcast of the objective device C108 at the step 80 can be omitted by a method for setting the destination to send the function limitation corresponding contents FCCa in advance, or a method for automatically sending the function limitation corresponding contents FCCa to the address to which the function limitation information FLCa. In such a case, the objective device C108 needs not have functions of implement broadcast.

According to the above embodiment, the digital broadcast receiving device connected to the objective device can perform the contents corresponding to the function limitation release as a proxy, and recovering of the limited function of the device can be performed. That can shorten a time period in which the device with the function limited to be used as it is. That can enhance security of the device.

At that moment, as the function limitation corresponding contents such as an updating software program can be obtained by the digital broadcast receiving device and a local area network, an effect of saving the resource such as a large-scale server setting or the network bandwidth can be expected.

In the fourth embodiment, the digital broadcast receiving device E213 may be a TV display device with a recording function or a recording device such as a hard disk recorder.

For example, the above-mentioned digital broadcast receiving device E may limit the operation of the function part therein if only it has the objective identifying information of the device determining information.

For the procedures of the flowcharts shown in FIGS. 6, 7, 11 to 14, and 17 to 19, all described in the drawings are not necessarily needed. With some designing methods, determination of a part of the flowcharts can be omitted or processing with particularly little influence may be added. With other designing methods, the order may be changed.

To the digital broadcast receiving device shown in the above-mentioned second to the fourth embodiments and the system including the device connected to the device by the information transferring part, the system including the digital broadcast receiving device and various devices connected via the wired information transferring part or the wireless information transferring part corresponds.

If the system is a system including an image display device such as one or more monitors, TVs, projectors and the like connected to the digital broadcast receiving device via the wired information transferring part or the wireless information transferring part, a part of the function relating to the image display can be limited or operations of the power section of the main function part of the device are limited, for example. That can shorten a time period in which an operation has a trouble or may be abused or the like due to the theft or the like. Thus, that can enhance security of the device.

If the system is a system including an audio output device such as one or more speakers or the like connected to the digital broadcast receiving device via the wired information transferring device or the wireless information transferring part, a part of the function relating to the audio output may be limited or operations of the power section of the main function part of the device may be limited, for example. That can shorten a time period in which an operation has a trouble or may be abused or the like due to the theft or the like. Thus, that can enhance security of the device.

If the system is a system including a data output device connected to the digital broadcast receiving device via the wired information transferring part or the wireless information transferring part, a part of the function relating to the data output may be limited or an operations of power section of the main function part of the device may be limited, for example. That can shorten a time period in which an operation has a trouble or may be abused or the like due to the theft or the like. Thus, that can enhance security of the device.

If the system is a system including a data recording device connected to the digital broadcast receiving device via the wired information transferring part or the wireless information transferring part, a part of the function relating to the data recording may be limited or operations of the power section of the main function part of the device can be limited, for example. That can shorten a time period in which an operation has a trouble or may be abused or the like due to the theft or the like. Thus, that can enhance security of the device.

If the system is a system including a PC connected to the digital broadcast receiving device via the wired information transferring part or the wireless information transferring part, a part of the function relating to permission of the PC may be limited or operations of the power section of the main function part of the device may be limited, for example. That can shorten a time period in which an operation has a trouble or may be abused or the like due to the theft or the like. Thus, that can enhance security of the device.

If the system is a system including a digital broadcast receiving device and a mobile device such as a vehicle, a ship and a plane connected by a wired information transferring part or a wireless information transferring part, it may limit a part of functions relating to movement of the mobile station or limit operations of power section of the main function part of the device. That can shorten a time period in which an operation has a trouble or may be abused or the like due to the theft or the like. Thus, that can enhance security of the device.

Thus, according to the present invention mentioned above, operations of the digital broadcast receiving device or the device connected to the digital broadcast receiving device are preferably limited to enhance security of the device.

It should be further understood by those skilled in the art that although the foregoing description has been made on embodiments of the invention, the invention is not limited thereto and various changes and modifications may be made without departing from the spirit of the invention and the scope of the appended claims.

1. A digital broadcast receiving device comprising:
a receiving part for receiving a digital broadcast signal comprising first identifying information; and
a control part;
wherein the control part compares the first identifying information comprised in the digital broadcast signal received at the receiving part and second identifying information comprised in the digital broadcast receiving device, and limits a function of the digital broadcast receiving device based on the comparison.

2. The digital broadcast receiving device according to claim 1, wherein
the control part limits the function, if the first identifying information and the second identifying information match.

3. The digital broadcast receiving device according to claim 1, wherein
the first identifying information comprises information for identifying a manufacturer, a model, a serial number, a version of hardware or a version of a software program of the device.

4. The digital broadcast receiving device according to claim 1, wherein there are a plurality of the function parts;
the digital broadcast signal further comprises function determining information for determining the function in the device;
the control part compares the first identifying information comprised in the digital broadcast signal received by the receiving part and the second identifying information comprised in the digital broadcast receiving device, and based on the comparison,
limits the function determined by the function determining information among a plurality of functions comprised in the device.

5. The digital broadcast receiving device according to claim 1, wherein the digital broadcast signal further comprises release information, and
the control part releases limitation on the function if the receiving part receives the release information after limiting the function.

6. The digital broadcast receiving device according to claim 1, wherein the function comprises any of a display function of an image based on a digital broadcast signal received by the receiving part, an output function of an audio based on the digital broadcast signal, and a power-on function of the device.

7. A digital broadcast receiving device that can download and update software information comprised in a digital broadcast signal, comprising
an information obtaining part for obtaining announcement information for announcing that the software information comprised in the digital broadcast signal is to be broadcasted and first identifying information, and
a control part;
wherein the control part limits the function of the digital broadcast receiving device, if the information obtaining part obtains the announcement information and the first identifying information and the second identifying information comprised in the digital broadcast receiving device match.

8. The digital broadcast receiving device according to claim 7, wherein
the limited function is a function corresponding to the updated software program.

9. The digital broadcast receiving device according to claim 7, wherein
the information obtaining means obtains the function determining information for determining a function from the digital broadcast signal, and
limits the function determined by the function determining information among a plurality of functions comprised in the digital broadcast receiving device as a function corresponding to the updated software information.

10. A digital broadcast receiving device, comprising:
a receiving part for receiving a digital broadcast signal comprising first identifying information;
a control part;
a storage part for storing connected device identifying information comprised in the second identifying information relating to the device connected to the digital broadcast receiving device; and
an information sending/receiving part;
wherein the control part compares the first identifying information comprised in the digital broadcast signal received at the receiving part and second identifying information comprised in the connected device information, and
based on the comparison,
the information sending/receiving part sends information for limiting a function of the connected device to the connected device.

11. The digital broadcast receiving device according to claim 10, further comprising:
an order generating part,
wherein the order generating part generates limitation order information for limiting a function based on the digital broadcast signal received by the receiving part;
the control part compares the first identifying information comprised in the digital broadcast signal received by the receiving part and the second identifying information comprised in the connected device information; and
based on the comparison,
the information sending/receiving part sends the limitation order information to the connected device.

12. The digital broadcast receiving device according to claim 10, wherein
the first and second identifying information comprises identifying information unique to the connected device, and if both identifying information match,
the information sending/receiving part sends information for stopping or forbidding operations of the connected device to the connected device.

13. The digital broadcast receiving device according to claim 10, wherein
if software information comprised in the digital broadcast signal can be downloaded and updated,
if the receiving part receives announcement information for announcing that the software information is broadcasted prior to the download, and
if the first identifying information and the second identifying information comprised in the digital broadcast receiving device match,
the information sending/receiving part sends information for limiting a function of the connected device to the connected device.

14. The digital broadcast receiving device according to claim 13, wherein
after information for limiting a function is sent to the connected device,
the receiving part receives software information comprised in the digital broadcast signal; and
the digital broadcast receiving device sends the software information to the connected device.

15. A function controlling method of a digital broadcast receiving device having a plurality of functions, comprising the steps of:
receiving a digital broadcast signal comprising function limitation information or function limitation corresponding contents;
comparing device determining information comprised in the received function limitation information and identifying information of the device;
obtaining function determining information comprised in the received function limitation information when the device determining information and the identifying information match; and
limiting a function of the device determined by the function determining information.

16. The function controlling method according to claim 15, further comprising the steps of:
receiving a digital broadcast signal comprising function release information, when the device determining information and the identifying information match; and
releasing function limitation of the device determined by the function release information.

17. The function controlling method according to claim 15, further comprising the step of releasing function limitation of the device determined by the received function limitation corresponding contents with the function release information.
